(19) United States
(12) Patent Application Publication
(10) Pub. No.: US 2002/0119628 A1
(43) Pub. Date: Aug. 29, 2002

(54) STI method for semiconductor processes

(76) Inventor: Erh-Kun Lai, Tai-Chung Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 09/840,999

(22) Filed: Apr. 25, 2001

(30) Foreign Application Priority Data
Feb. 23, 2001 (TW) 090104264

(51) Int. Cl. H01L 21/336

(52) U.S. Cl. 438/296

(57) ABSTRACT

The preferred embodiment of the present invention comprises the following steps: (1) providing a substrate; (2) forming a stacked mask on the substrate, wherein the stacked mask has an opening exposing portions of the underlying substrate, and comprises a pad oxide layer and a silicon layer stacked on the pad oxide layer; (3) performing a first dry etching process to form a trench in the surface of the substrate through the opening; (4) performing an oxidation process to simultaneously form a liner on an interior surface of the trench and an oxide layer with a predetermined thickness on the silicon layer; (5) depositing an insulating layer on the oxide layer and the liner; (6) performing a planarization process to remove the insulating layer and the oxide layer atop the silicon layer, thereby exposing the silicon layer and the remaining oxide layer, which functions to protect the STI corner regions; and (7) performing a second dry etching process to remove the silicon layer.

### BACKGROUND OF THE INVENTION

1. Field of the Invention

The present invention relates to a Shallow Trench Isolation (STI) method for high integration semiconductor processes, and more particularly, to a method of STI fabrication with oxidized silicon spacers for protecting STI corner regions and, at the same time, preventing the Kooi Effect and the stress effects induced by silicon nitride layers.

2. Description of the Prior Art

As packing density increases dramatically, the traditional LOCOS (Local Oxidation of Silicon) technique is no longer adequate for current ULSI semiconductor front-end processes. In semiconductor front-end processes, an STI (Shallow Trench Isolation) technique is now readily used to provide sufficient isolation between electrical devices in integrated circuits. A typical STI process involves the formation of shallow trenches surrounding an active island, referred to as an “active area”, on the wafer. Then, an oxide layer or a liner is thermally formed on the interior surface of the trenches, followed by filling in the trenches with an insulating material to obtain an electrical isolation effect.

Please refer to FIGS. 1A to 1C. FIGS. 1A to 1C are schematic diagrams showing the steps for making an STI according to the prior art method. The steps comprise: (1) providing a silicon substrate 101; (2) growing a pad oxide layer 102; (3) depositing a silicon nitride layer 103; (4) forming a trench 100; (5) thermally forming a liner 104; (6) performing high-density plasma chemical vapor deposition (HDPCVD) to fill the trench 100 with HDP oxide 105; (7) chemical mechanical polishing of the HDP oxide 105; and (8) removing the silicon nitride layer 103 and cleaning the polished surface of the silicon substrate 101.

However, as shown in FIG. 1C, oxide-recesses 106 are usually observed after the STI cleaning step, due to weak resistance of the interface of the STI corner region 107 and the filling material 105 to cleaning solution. The oxide-recesses 106 are most likely the major cause of semiconductor device malfunctions, such as the undesirable double-hump on the Id/Vg curve of a MOS transistor. Further, the use of a silicon nitride layer, which functions as a stop layer leads to the Kooi Effect, reducing the reliability of devices. The silicon nitride layer 103 is a tensile stress film, thus the substrate suffers stress induced by the silicon nitride layer 103. To reduce this stress, prior art STI methods usually adopt a SAC process.

In U.S. Pat. No. 5,801,083, Yu et al. discloses an alternative method of forming an STI. Yu uses polymer spacers during the fabrication of the STI. After completion of the trench formation, the polymer spacers are removed, exposing a region of unetched semiconductor protected by the polymer spacers during the shallow trench dry etching procedure. The sharp corner at the intersection between the trench and the unetched region is then converted to a rounded corner, via thermal oxidation of the exposed silicon surfaces. Unfortunately, Yu does not teach how to prevent the formation of oxide-recesses during subsequent cleaning processes and the Kooi Effect caused by the use of the silicon nitride stop layer. Furthermore, the method taught by Yu et al. is complicated and is subject to contamination resulting from the use of polymer spacers.

### SUMMARY OF THE INVENTION

It is therefore a primary objective of the present invention to provide an STI method for preventing oxide recesses and the Kooi Effect by eliminating the use of a silicon nitride stop layer.

Another objective of the present invention is to provide an STI method with an oxidized amorphous/polysilicon spacer to protect STI corner regions.

The preferred embodiment of the present invention involves the following steps:

(1) providing a substrate;

(2) forming a stacked mask on the substrate, wherein the stacked mask has an opening, exposing portions of the underlying substrate, and comprises a pad oxide layer and a silicon layer stacked on the pad oxide layer;

(3) performing a first dry etching process to form a trench in the surface of the substrate through the opening;

(4) performing an oxidation process to simultaneously form a liner on an interior surface of the trench and an oxide layer with a predetermined thickness on the silicon layer;

(5) depositing an insulating layer on the oxide layer and the liner;

(6) performing a planarization process to remove the insulating layer and the oxide layer atop the silicon layer, thereby exposing the silicon layer and the remaining oxide layer, which functions to protect the STI corner regions; and

(7) performing a second dry etching process to remove the silicon layer.

### BRIEF DESCRIPTION OF THE DRAWINGS

FIGS. 1A to 1C are schematic diagrams showing the steps for making an STI according to the prior art method.

FIGS. 2A to 2I are schematic diagrams showing a preferred embodiment according the present invention.

FIGS. 3A to 3C are schematic diagrams showing another embodiment according the present invention.

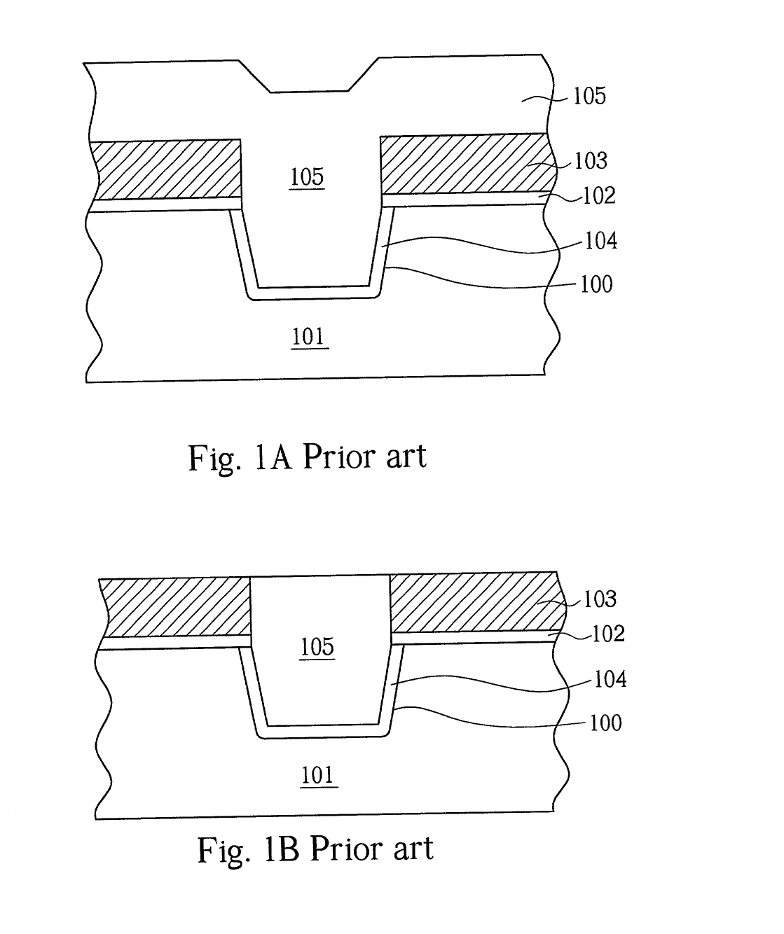

### DETAILED DESCRIPTION OF THE PRESENT INVENTION

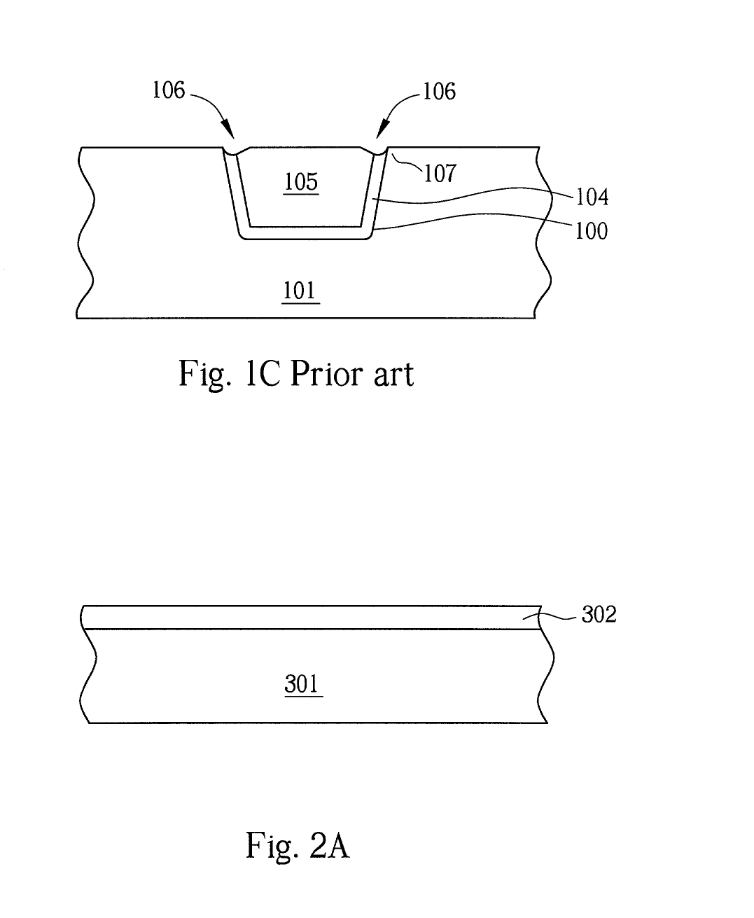

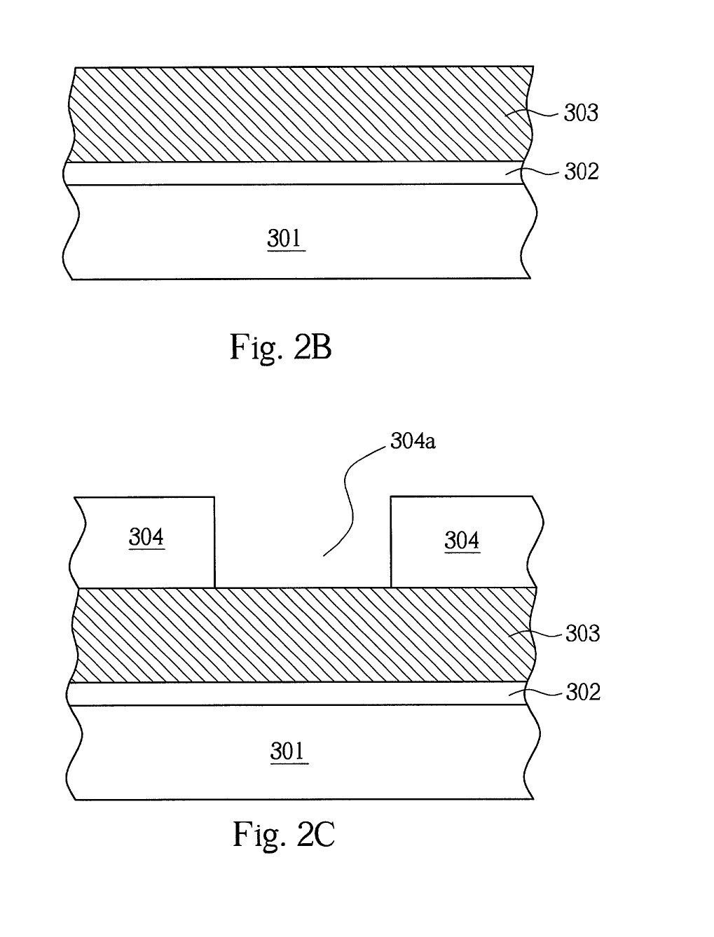

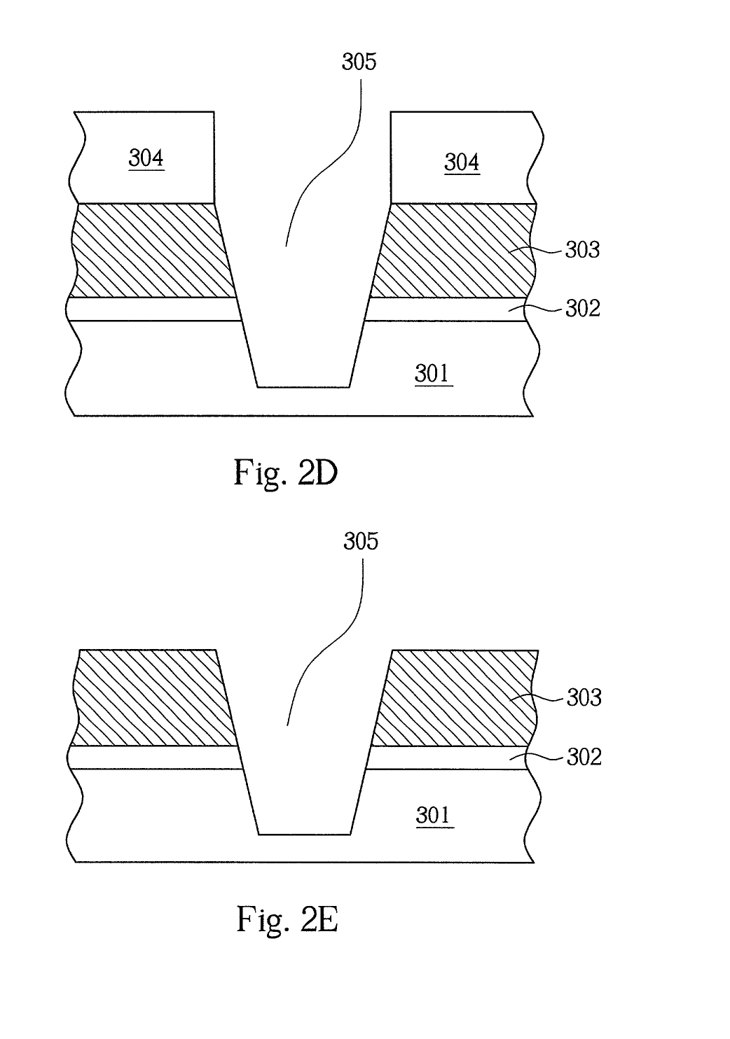

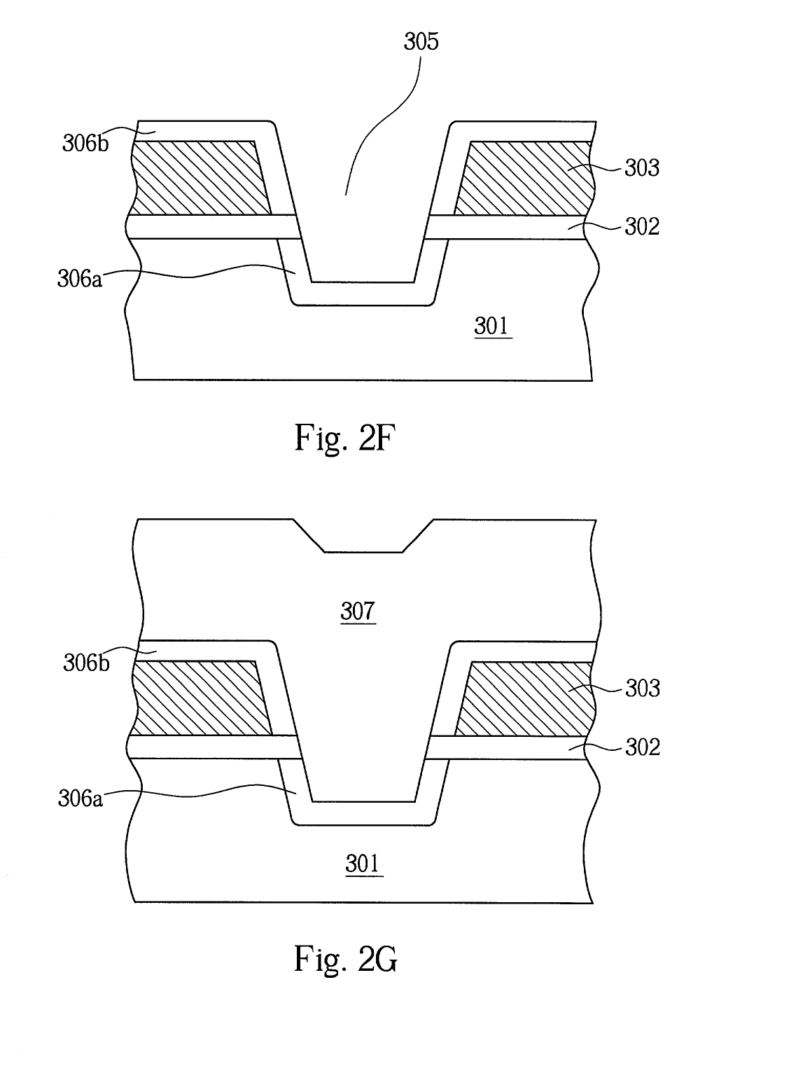

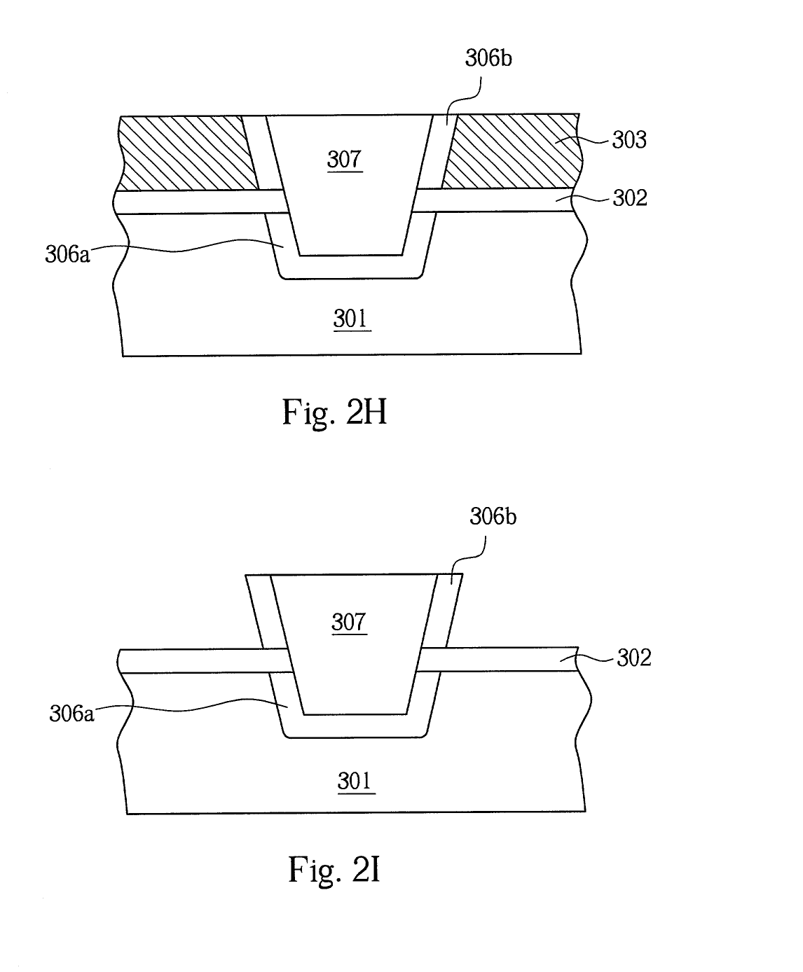

Referring to FIGS. 2A to 2I, the STI formation according to the preferred embodiment of the present invention shall be described in detail. First, as shown in FIG. 2A, a silicon substrate 301 is provided. In the preferred embodiment of the present invention, the substrate 301 is a P-type silicon substrate with a <100> crystalline orientation. The method of the present invention is applied not only to the P-type silicon substrate but also to variants, such as a silicon-on-insulator (SOI) substrate or an epitaxial silicon substrate. A 50 to 300 angstroms thick pad oxide layer 302 is then formed on the silicon substrate 301. The pad oxide layer 302 is formed by conventional thermal oxidation in an oxygen-rich environment. In a preferred embodiment of the present invention, the thickness of the pad oxide layer 302 is about 200 angstroms.

As shown in FIG. 2B, a silicon layer 303, preferably an amorphous silicon layer, is then deposited on the pad oxide layer to a thickness of about 800 to 2500 angstroms, preferably 1600 angstroms. The amorphous silicon layer 303 is deposited via a chemical vapor deposition method, with silane (SiH₄) as a reactant, under 0.4 Torr, a temperature from 450° C. to 580° C. (preferably 530° C.), and the flow rate of silane being about 450 to 500 sccm, resulting in a deposition rate of about 17 Å/min.

In other embodiments, the silicon layer 303 may be composed of polysilicon. In this case, a polysilicon layer 303 is deposited on the pad oxide layer to a thickness of about 800 to 2500 angstroms, preferably 1600 angstroms. The amorphous silicon layer 303 is deposited using chemical vapor deposition, with silane as a reactant, under 160 Torr, a temperature of 580° C. to 700° C. (preferably 620° C.), and the flow rate of silane being about 450 to 500 sccm (preferably 475 sccm), resulting in a deposition rate of about 104 Å/min.

As shown in FIG. 2C, a resist layer 304 is formed on the silicon layer 303 by way of a conventional lithographic process. The resist layer 304 has a trench pattern opening 304a exposing portions of the underlying silicon layer 303 to be etched away in a subsequent etching process. The lithographic process comprises a resist coating step, exposure, development, and several baking steps. As shown in FIG. 2D, using the resist layer 304 as an etch mask, a reactive ion etching (RIE) process is performed to etch the silicon layer 303, the pad oxide layer 302 and the silicon substrate 301 through the trench pattern opening 304a, thereby forming a trench 305. As FIG. 2E shows, the resist layer 304 is stripped, exposing the underlying silicon layer 303.

As shown in FIG. 2F, a high temperature oxidation process is performed at a temperature of about 950° C. to 1150° C. to simultaneously form a liner oxide layer 306a on the interior surface of the trench 305 and a 100 to 300 angstroms thick oxide layer 306b on the exposed surface of the silicon layer 303.

As shown in FIG. 2G, a high-density plasma CVD (HDP CVD) process is then performed to form an insulating layer 307 and to fill the trench 305. In addition, the insulating layer 307 may be composed of CVD oxide, FSG, PSG, BPSG, or SOC (spin-on-coating) materials. As shown in FIG. 2H, a CMP process is performed to remove the insulating layer 307 atop the silicon layer 303 and also the oxide layer 306b atop the silicon layer, using the silicon layer 303 as a stop layer, thereby exposing the silicon layer 303. The remaining portion of the oxide layer 306b, approximately equal to the thickness of the oxide layer 306b, protects the STI corner region. As shown in FIG. 2I, a dry etching process with CF₄, Cl₂, HBr, He, and oxygen as reactants is performed to completely remove the silicon layer 303. Preferably, a 70 second overetch is performed after the dry etch endpoint.

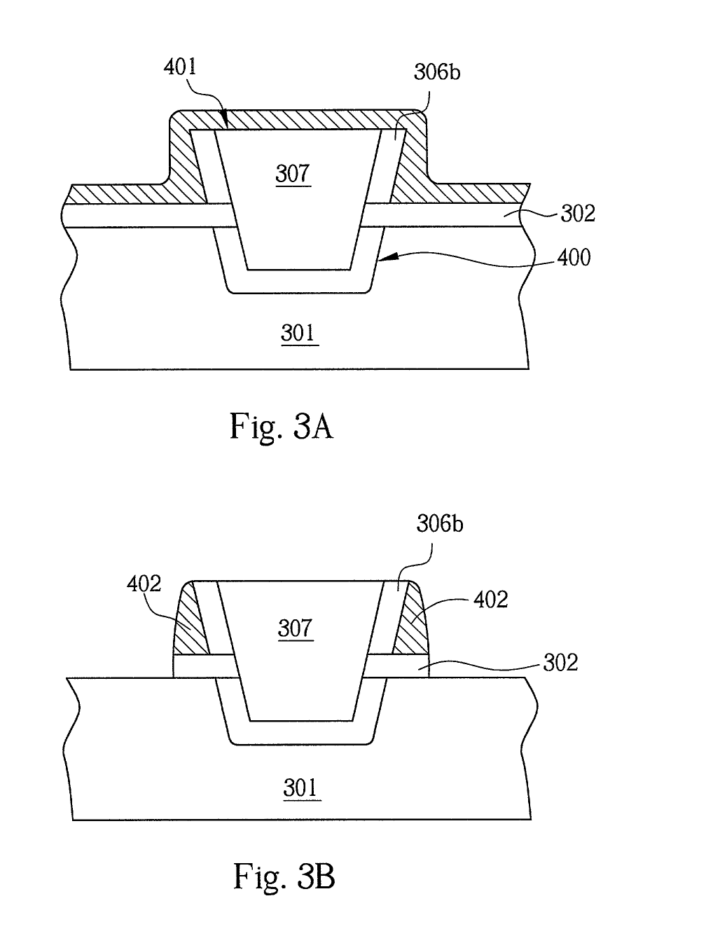

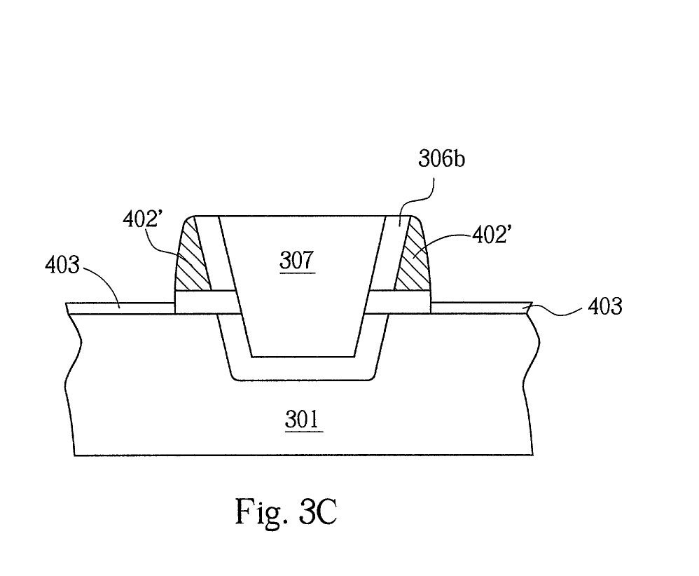

Referring to FIGS. 3A to 3C, an STI formation according to another embodiment of the present invention will now be described in detail. To achieve the goal of the present invention, a reinforcement step is added to the above-preferred embodiment. As shown in FIG. 3A, at least one STI structure 400, filled with an insulating layer 307, is formed on a silicon substrate 301. Likewise, as mentioned in the preferred embodiment, the corner regions of the STI structure 400 are protected by the oxide layer 306b. The formation of the oxide layer 306b is the same as the preferred embodiment, and is thus omitted in this embodiment. A polysilicon deposition is performed at a pressure of 150 to 200 Torr, and a temperature of 580° C. to 700° C., with silane as a reactant, to deposit a polysilicon layer 401 over the silicon substrate 301 and the STI structure 400. The preferred thickness of the polysilicon layer 401 is 100 to 1000 angstroms, preferably 300 to 600 angstroms.

As shown in FIG. 3B, an etch back process is then performed to form a polysilicon spacer on the oxide layer 306b of each wall of the STI structure 400. The etch back process is halted on the pad oxide layer 302, or on the silicon substrate 301. When the etch back process is stopped on the pad oxide layer 302, an additional cleaning process is used to etch away the pad oxide layer 302.

Finally, as shown in FIG. 3C, an oxidation process, such as dry oxidation, wet oxidation, dry-wet-dry oxidation, ozone oxidation, or furnace oxidation, is performed to simultaneously form an oxide layer 403 on the silicon substrate 301, and oxidize the polysilicon spacer 402 to become an oxidized polysilicon spacer 402′. The oxidation extent of the polysilicon spacer 402 in the oxidation process depends on the desired thickness of the oxide layer 403 and the reaction rate of the oxidation process. Usually, the oxide layer 403 functions as a gate oxide layer for a MOS transistor. It is clear that the oxidized polysilicon spacer 402′ can extend the protected region around the STI corner region.

In comparison with the prior art method, the features of the present invention can be summarized as follows:

(1) a silicon nitride layer is not used during the formation of an STI;

(2) prevention of the Kooi Effect and the stress induced by silicon nitride layers;

(3) protected STI corner regions by the oxide layer 306b.

Those skilled in the art will readily observe that numerous modifications and alterations of the device may be made while retaining the teachings of the invention. Accordingly, the above disclosure should be construed as limited only by the metes and bound of the appended claims.

What is claimed is:

1. A shallow trench isolation (STI) process, comprising:
providing a substrate;
forming a stacked mask on the substrate, wherein the stacked mask has an opening exposing portions of the underlying substrate and comprises a pad oxide layer and a silicon layer stacked on the pad oxide layer;
performing a first dry etching process to form a trench in the surface of the substrate through the opening;
performing an oxidation process to simultaneously form a liner on an interior surface of the trench and an oxide layer with a predetermined thickness on the silicon layer;
depositing an insulating layer on the oxide layer and the liner;
performing a planarization process to remove the insulating layer and the oxide layer atop the silicon layer, thereby exposing the silicon layer and the remaining oxide layer to protect STI corner regions; and
performing a second dry etching process to remove the silicon layer.

2. The STI process of claim 1 wherein the silicon layer is composed of polysilicon or amorphous silicon.

3. The STI process of claim 2 wherein the silicon layer has a thickness of about 800 to 2500 angstroms.

4. The STI process of claim 1 wherein the predetermined thickness is 100 to 600 angstroms.

5. The STI process of claim 1 wherein the oxidation process is performed at a temperature of 950° C. to 1150° C.

6. The STI process of claim 1 wherein the insulating layer is formed by a high density plasma chemical vapor deposition (HDPCVD) method.

7. The STI process of claim 1 wherein the insulating layer is formed by a spin-on-coating method.

8. The STI process of claim 1 wherein the substrate is an SOI (silicon-on-insulator) substrate.

9. A shallow trench isolation (STI) process having a reduced Kooi effect, the process comprising:
providing a substrate;
forming a pad oxide layer on the substrate;
forming a silicon layer on the pad oxide layer;
forming a resist layer on the silicon layer, wherein the resist layer has at least one opening exposing portions of the underlying silicon layer;
performing a first dry etching process to etch away the silicon layer, pad oxide layer, and the substrate through the opening, thereby forming a trench in the substrate;
removing the resist layer;
performing an oxidation process to simultaneously form a liner on an interior surface of the trench and an oxide layer with a predetermined thickness on the silicon layer;
depositing an insulating layer on the oxide layer and the liner and filling the trench;
performing a chemical mechanical polishing (CMP) process to polish the insulating layer and the oxide layer atop the silicon layer, thereby exposing the silicon layer and the remaining oxide layer to protect STI corner regions; and
performing a second dry etching process to remove the silicon layer.

10. The STI process of claim 9 wherein the silicon layer is composed of polysilicon or amorphous silicon.

11. The STI process of claim 10 wherein the silicon layer has a thickness of about 800 to 2500 angstroms.

12. The STI process of claim 9 wherein the predetermined thickness is 100 to 600 angstroms.

13. The STI process of claim 9 wherein the oxidation process is performed at a temperature of 950° C. to 1150°0 C.

14. The STI process of claim 9 wherein the insulating layer is formed by a high density plasma chemical vapor deposition (HDPCVD) method.

15. The STI process of claim 9 wherein the insulating layer is formed by a spin-on-coating method.

16. The STI process of claim 9 wherein the substrate is an SOI (silicon-on-insulator) substrate.
